(19) United States
(12) Patent Application Publication
(10) Pub. No.: US 2026/0182348 A1
(43) Pub. Date: Jun. 25, 2026

(54) SEMICONDUCTOR DEVICES INCLUDING VOIDS HAVING DIFFERENT DEPTHS

(71) Applicant: GlobalFoundries Singapore Pte. Ltd., Singapore (SG)

(72) Inventor: ANTHONY JEREMY VILLALON, Singapore (SG)

(21) Appl. No.: 18/986,786

(22) Filed: Dec. 19, 2024

(51) Int. Cl. H01L 23/528; H01L 21/764

(52) U.S. Cl. CPC H10W 20/435; H10W 10/021; H10W 10/20

(57) ABSTRACT

The embodiments herein relate to semiconductor devices including voids having different depths and methods of forming the same. The semiconductor device includes a device layer, a first metal layer over the device layer, a second metal layer over the first metal layer, a first void, and a second void. The device layer may include an active component. The first void is vertically over the active component and arranged through the first metal layer and the second metal layer. The second void is adjacent to the first void and has an upper portion at a same level as an upper portion of the first void.

### TECHNICAL FIELD

The present disclosure relates generally to semiconductor devices, and more particularly to semiconductor devices including voids having different depths and methods of forming the same.

### BACKGROUND

Advancements in the semiconductor integrated circuit (IC) industry have led to smaller IC chips with a higher density of semiconductor devices. Miniaturization, or downsizing, is key to improving overall device performance. As semiconductor devices continue to shrink in size, capacitive coupling between adjacent electrically conductive elements, such as metal wires, also increases. The rise in capacitive coupling results in a higher level of parasitic capacitance, which negatively impacts the overall performance of the devices. Voids, or air gaps, are commonly used to improve electrical isolation between the electrically conductive elements, thereby reducing the level of parasitic capacitance therebetween.

Voids can provide intra-metal layer electrical isolation through conventional techniques known in the art. For extended electrical isolation, intra-metal layer voids can be vertically stacked in adjacent metal layers, such that an upper intra-metal layer void merges with a lower intra-metal layer void. However, such a fabrication method is costly and poses several processing challenges, such as the need for an additional patterning mask and/or insufficient depth of an upper intra-metal layer void to merge with a void in a lower intra-metal layer, leading to less ideal electrical isolation.

Accordingly, to meet the growing needs of the semiconductor industry, semiconductor devices enabling further device miniaturization without penalizing device performance, and methods of forming the same are provided.

### SUMMARY

To achieve the foregoing and other aspects of the present disclosure, semiconductor devices including voids having different depths and methods of forming the same are presented.

According to an aspect of the present disclosure, a semiconductor device is provided. The semiconductor device includes a device layer, a first metal layer over the device layer, a second metal layer over the first metal layer, a first void, and a second void. The device layer may include an active component. The first void is vertically over the active component and arranged through the first metal layer and the second metal layer. The second void is adjacent to the first void and has an upper portion at a same level as an upper portion of the first void.

According to another aspect of the present disclosure, a method of forming a plurality of voids in a semiconductor device is provided. The method includes forming a device layer including an active component and forming a first metal layer over the device layer. A second metal layer is formed over the first metal layer. A first void and a second void are formed. The first void is formed through the first metal layer and the second metal layer and is arranged vertically over the active component. The second void is adjacent to the first void and has an upper portion at a same level as an upper portion of the first void.

### BRIEF DESCRIPTION OF THE DRAWINGS

The embodiments of the present disclosure will be better understood from a reading of the following detailed description, taken in conjunction with the accompanying drawings.

FIGS. 1-5 are cross-sectional views of a semiconductor device at successive fabrication stages of a processing method, according to an embodiment of the disclosure.

For simplicity and clarity of illustration, the drawings illustrate the general manner of construction, and certain descriptions and details of features and techniques may be omitted to avoid unnecessarily obscuring the discussion of the described embodiments of the device.

Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The present disclosure relates to semiconductor devices, and more particularly to semiconductor devices including voids having different depths and methods of forming the same. Various embodiments of the present disclosure are now described in detail with accompanying drawings. It is noted that like and corresponding elements are referred to by the use of the same reference numerals. The embodiments disclosed herein are exemplary, and not intended to be exhaustive or limiting to the disclosure.

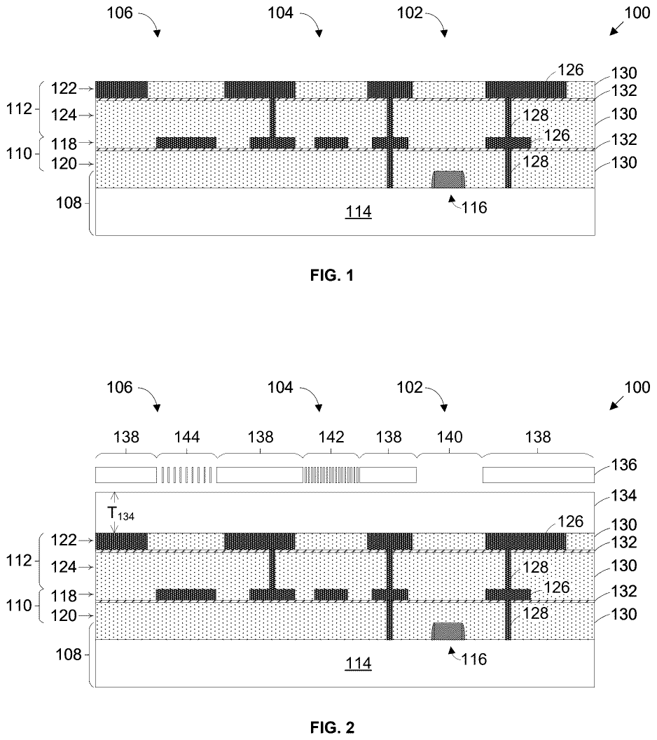

FIGS. 1 to 5 are cross-sectional views of a semiconductor device 100 at successive fabrication stages of a processing method, according to an embodiment of the disclosure. The semiconductor device 100 may have areas that require enhanced electrical isolation and voids providing intra-metal layer electrical isolation and inter-metal electrical isolation may be arranged therein. As illustrated in FIG. 1, three (3) areas 102, 104, 106 in the semiconductor device 100 may require enhanced electrical isolation.

Certain structures may be fabricated, for example, using known processes and techniques, and specifically disclosed processes and methods may be used to achieve individual aspects of the present disclosure. The below-described order for the method of forming the semiconductor device 100 is intended to be illustrative, and the method is not limited to the specifically described order unless otherwise specifically stated.

As used herein, “deposition techniques” refer to the process of applying a material over another material. Exemplary techniques for deposition include, but not limited to, spin-on coating, sputtering, chemical vapor deposition (CVD), physical vapor deposition (PVD), molecular beam deposition (MBD), pulsed laser deposition (PLD), liquid source misted chemical deposition (LSMCD), or atomic layer deposition (ALD).

Additionally, “patterning techniques” include deposition of material or photoresist, patterning, exposure, development, etching, cleaning, and/or removal of the material or photoresist as required in forming a described pattern, structure, or opening. Exemplary examples of techniques for patterning include, but not limited to, wet etch photolithographic processes, dry etch photolithographic processes, or direct patterning processes.

Referring to FIG. 1, the semiconductor device 100 may include a device layer 108 and a multi-stack level of interconnect layers, such as a first interconnect layer 110 and a second interconnect layer 112, over the device layer 108. The device layer 108 may include a substrate 114. The substrate 114 may be a bulk semiconductor substrate, as illustrated, or a composite semiconductor substrate, such as a semiconductor-on-insulator (SOI) substrate 114 including a base substrate, a buried insulator layer over the base substrate, and a semiconductor layer over the buried insulator layer. The substrate 114 may include a semiconductor material, such as silicon, germanium, silicon germanium, silicon carbide, or other II-VI or III-V semiconductor compounds.

The device layer 108 may also include one or more electrically conductive active components 116 having the ability to control the electrical current, such as transistors, triode vacuum tubes (valves), or tunnel diodes. The exemplary active component 116 illustrated in FIG. 1 is a transistor. The device layer 108 may, additionally or optionally, include passive components (not shown). The passive components may be incapable of controlling electrical current by means of another electrical signal and may include resistors, capacitors, or inductors.

The first interconnect layer 110 may include a metal layer 118 and a via layer 120 under the metal layer 118. The second interconnect layer 112 may include a metal layer 122 and a via layer 124 under the metal layer 122. The metal layers 118, 122 may each include metal wires 126 that extend mostly horizontally or laterally in the respective metal layers 118, 122 to carry electrical signals, such as an electrical current, across the semiconductor device 100. The via layers 120, 124 may each include via structures 128 that extend mostly vertically to provide an electrical connection between the metal wires 126 to ensure electrical continuity between the metal layers 118, 122. The metal wires 126 and via structures 128 may include a metallic material, such as tungsten, copper, aluminum, cobalt, or alloys thereof.

In some implementations, the metal layers 118, 122 may be referred to as “Mx”, with the letter “x” in the term “Mx” being an integer referencing the level of interconnect layers at which the metal layers 118, 122 are arranged. For example, the metal layer 118 may be referred to as “M1” and the metal layer 122 above M1 may be referred to as “M2”. Similarly, the via layers 120, 124 may be referred to as “Vx”, with the letter “x” in the term “Vx” being an integer referencing the level of interconnect layers at which the via layers are arranged. For example, the via layer 120 may be referred to as “V0” or contacts, and the via layer 124 may be referred to as “V1”. V0 may electrically connect M1 to the device layer 108 of the semiconductor device 100, and V1 may electrically connect M1 to M2.

Each interconnect layer 110, 112 may include an interlayer dielectric (ILD) 130. The ILD 130 may include an electrically insulative material, such as silicon oxide, silicon oxynitride, borophosphosilicate glass (BPSG), or undoped silicate glass (USG), and may be formed from any number of dielectric layers. Each interconnect layer 110, 112 may further include a dielectric layer 132 separating the metal layers 118, 122 from the via layers 120, 124 in the respective interconnect layers 110, 112. The dielectric layer 132 may include one or more layers of dielectric material, such as silicon nitride or silicon carbonitride, which is a different material from the ILD 130. The dielectric layer 132 may serve as an etch stop layer for the formation of the metal wires 126 in the metal layers 118, 122.

FIG. 2 is a cross-sectional view of the semiconductor device 100 at a fabrication stage after FIG. 1, according to an embodiment of the disclosure. A photoresist layer 134 may be formed over the semiconductor device 100. The photoresist layer 134 may be formed of a light-sensitive material. As an exemplary example in this present disclosure, the photoresist layer 134 may include a positive photoresist material that dissolves in a chemical solution, commonly referred to as a developer, after being exposed to light, such as ultraviolet (UV) light, during a photoresist development process. Alternatively, the photoresist layer 134 may include a negative photoresist material that hardens after being exposed to light, making the exposed area resistant to the chemical solution during the photoresist development process. The photoresist layer 134 may be deposited using a deposition technique, including a spin-coating process, to a thickness T₁₃₄.

The photoresist layer 134 may undergo a lithography process, in particular, a grayscale lithography process. The grayscale lithography process, similar to conventional lithography processes, may include the use of a mask 136. The mask 136 may include patterns, i.e., openings, which will be subsequently transferred to the photoresist layer 134 upon exposure to light. However, grayscale lithography enables control of the local exposure of the photoresist layer 134 through a spatial light modulator of sub-wavelength pixels on the mask 136. The pattern density of the pixels is lower than the printing resolution of the lithography process, thus the patterns of the mask 136 will not be transferred to the photoresist layer 134. The pixels may instead control the amount of light passing through the mask 136 to the photoresist layer 134.

Accordingly, the mask 136 may include areas where the passage of light is modulated and where light transmission can vary from no light (i.e., 0% light transmission) passing through the mask 136 to all light (i.e., 100% light transmission) passing through the mask 136. For example, the mask 136 may include a mask area 138 where light is completely blocked (i.e., 0% light transmission), a mask area 140 where light is completely transmitted (i.e., 100% light transmission), and mask areas 142, 144 where a percentage of light is transmitted through the mask 136, the percentage may be between 0% to 100%.

The mask areas 140, 142, 144 may include different pattern densities to modulate the amount of light passing through. For example, the mask area 140 may have a first pattern density, or zero pattern density as shown, to allow 100% light transmission. The mask area 142 may have a second pattern density higher than the first pattern density, and the mask area 144 may have a third pattern density higher than the first pattern density but lower than the second pattern density. The varying pattern densities of the mask 136 allow different amounts of light to pass through, i.e., the higher the pattern density, the less light will pass through the mask 136, resulting in varying levels of exposure of the photoresist layer 134 underneath the mask 136. In an embodiment of the disclosure, the mask area 140 may be arranged over the active component 116.

FIG. 3 is a cross-sectional view of the semiconductor device 100 at a fabrication stage after FIG. 2, according to an embodiment of the disclosure. After portions of the photoresist layer 134 have been exposed to light through the mask 136, the photoresist layer 134 may undergo a photoresist development process that selectively removes the exposed portions to form resist openings 146, 148, 150 in the photoresist layer 134.

Due to the varying levels of exposure received by the photoresist layer 134 through the mask 136, the amount of photoresist layer 134 remaining after the photoresist development process may vary. For example, light is completely blocked in the mask area 138 and therefore the corresponding portion of photoresist layer 134 underneath the mask area 138 will remain unmodified by the subsequent photoresist development process. The photoresist layer 134 underneath the mask areas 140, 142, 144 may be modified by light to varying degrees due to the varying levels of light transmission through the mask 136, and therefore the amount of photoresist layer 134 removed in the subsequent photoresist development process may be different.

As illustrated, the resist opening 146 may be formed through the photoresist layer 134 due to the corresponding portion of the photoresist layer 134 receiving the greatest amount of light through the mask area 140. The resist opening 146 may have a depth D₁₄₆ corresponding to the thickness T₁₃₄ of the photoresist layer 134. The resist opening 146 may expose a portion of the uppermost metal layer which, as shown, includes the second metal layer 122 of the second interconnect layer 112. The second metal layer 122 is over the second via layer 124 of the second interconnect layer 112, which in turn is over the first metal layer 118 and the first via layer 120 of the first interconnect layer 110, which is over the device layer 108.

The resist opening 148 may be formed partially through the photoresist layer 134 and may have a depth D₁₄₈. The depth D₁₄₈ may be shallower than depth D₁₄₆ due to the corresponding area of the photoresist layer 134 receiving a relatively lesser amount of light through the mask area 142 than the mask area 140. Accordingly, some photoresist material may remain under the resist opening 148, and the remaining photoresist material may have a thickness T₁₄₈. The resist opening 150 may also be formed partially through the photoresist layer 134 and may have a depth D₁₅₀ deeper than depth D₁₄₈ but shallower than depth D₁₄₆. Similarly, some photoresist material may remain under the resist opening 150, and the remaining photoresist material may have a thickness T₁₅₀, and the thickness T₁₅₀ may be thinner than the thickness T₁₄₈.

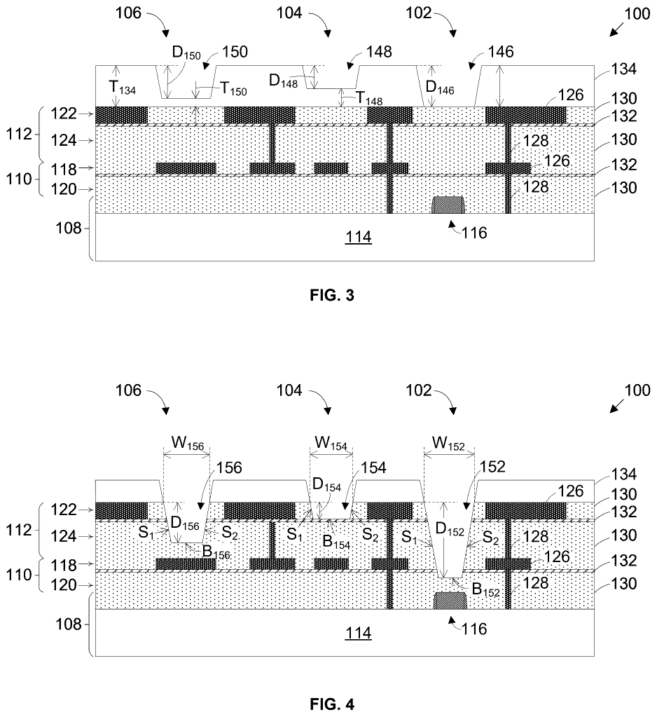

FIG. 4 is a cross-sectional view of the semiconductor device 100 at a fabrication stage after FIG. 3, according to an embodiment of the disclosure. The semiconductor device 100 may undergo a patterning technique, including an etching process, using the patterned photoresist layer 134 as a mask to form recesses 152, 154, 156 in the semiconductor device 100.

The recesses 152, 154, 156 may have different depths extending downwardly from the uppermost metal layer, such as the second metal layer 122 of the second interconnect layer 112, through the different interconnect layers. For example, the recess 152 may be formed through the second interconnect layer 112 and through at least the first metal layer 118 of the first interconnect layer 110, to a depth D₁₅₂. The recess 152 may expose an edge of the dielectric layers 132 and an edge of the ILD 130 in the first interconnect layer 110 and the second interconnect layer 112. The recess 152 may have an overlapping relationship with the active component 116 in the device layer 108 of the semiconductor device 100. For example, the recess 152 may be vertically aligned with the active component 116, though not necessarily in perfect alignment.

The recess 154 may be formed through the second metal layer 122 of the second interconnect layer 112 to a depth D₁₅₄. A portion of the dielectric layer 132 in the second interconnect layer 112 and an edge of the ILD 130 above the dielectric layer 132 may be exposed in the recess 154. The recess 156 may also be formed through the second metal layer 122 and may extend partially through the second via layer 124 of the second interconnect layer 112 to a depth D₁₅₆. The depth D₁₅₆ may be between depth D₁₅₂ and depth D₁₅₄. The recess 156 may expose an edge of the dielectric layer 132 and an edge of the ILD 130 of the second interconnect layer 112.

Each recess 152, 154, 156 may have opposite sidewalls S₁, S₂ extending downwardly and inwardly from the uppermost metal layer, such as the second metal layer 122. The sidewalls S₁, S₂ may include the exposed edges of the ILD 130, and for the recesses 152, 156, the sidewalls S₁, S₂ may further include exposed edges of the dielectric layer 132. The sidewalls S₁, S₂ may be substantially straight with a substantially uniform gradient of an absolute value. Accordingly, the uniformity in the gradient characteristic may be across all recesses 152, 154, 156 in the semiconductor device 100.

Each recess 152, 154, 156 may have a width dimension extending between their respective sidewalls S₁, S₂, and a maximum width W₁₅₂, W₁₅₄, W₁₅₆ at an opening of the recesses 152, 154, 156. The opening of the recesses 152, 154, 156 may be indicated by the highest point of the sidewalls S₁, S₂. The maximum widths W₁₅₂, W₁₅₄, W₁₅₆ of the recesses 152, 154, 156 may be at the same level in the second interconnect layer 112, such as the upper plane of the second metal layer 122. The width dimensions of the recesses 152, 154, 156 may vary with position along a plane that extends between the corresponding sidewalls S₁, S₂. For example, the width dimensions of the recesses 152, 154, 156 may decrease with increasing distance from the maximum width dimensions W₁₅₂, W₁₅₄, W₁₅₆. In an embodiment of the disclosure, the width dimensions of the respective recesses 152, 154, 156 may vary along the plane based on the same linear function.

Each recess 152, 154, 156 may further include a base surface B₁₅₂, B₁₅₄, B₁₅₆. The base surfaces B₁₅₂, B₁₅₄, B₁₅₆ may be in contact with the corresponding sidewalls S₁, S₂ of the recesses 152, 154, 156 at opposite ends. The base surfaces B₁₅₂, B₁₅₄, B₁₅₆ of the recesses 152, 154, 156 may be at different levels due to the different depths D₁₅₂, D₁₅₄, D₁₅₆ of the recesses 152, 154, 156. For example, the base surface B₁₅₂ of the recess 152 may be at a level below the base surfaces B₁₅₄, B₁₅₆ of the respective recesses 154, 156. In another example, the base surface B₁₅₂ of the recess 152 may be at a level below the metal layer 118 and the base surfaces B₁₅₄, B₁₅₆ of the respective recesses 154, 156 may be at a level above the metal layer 118.

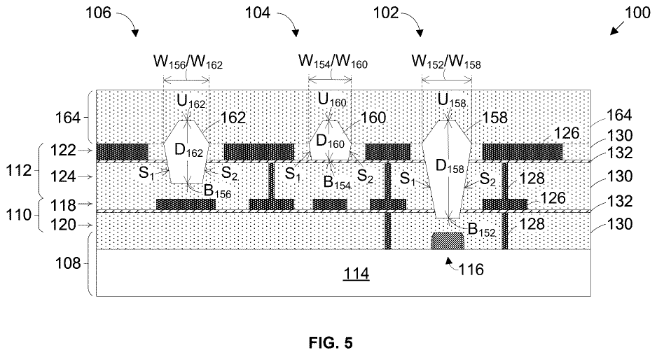

FIG. 5 is a cross-sectional view of the semiconductor device 100 at a fabrication stage after FIG. 4, according to an embodiment of the disclosure. The photoresist layer 134 may be removed by conventional resist stripping techniques, such as an ashing process and/or an etching process.

The recesses 152, 154, 156 may be sealed to form voids 158, 160, 162 by forming a dielectric layer 164 at a surface of the uppermost metal layer to seal the recesses 152, 154, 156. The dielectric layer 164 may serve as a capping layer to seal the recesses 152, 154, 156, and also as an ILD layer for the next interconnect layer above the second interconnect layer 112. The voids 158, 160, 162 may vertically extend partially into the dielectric layer 164 such that upper portions of the voids 158, 160, 162 are at a same level. The voids 158, 160, 162 may be formed entirely within a dielectric material of the interconnect layers, i.e., the voids 158, 160, 162 may be collectively surrounded by the ILD 130 and the dielectric layer 132 from under and laterally, and by the dielectric layer 164 from above, which fully seals the voids 158, 160, 162. The voids 158, 160, 162 may be contiguous through the one or more interconnect layers, i.e., there is no break in the voids.

The voids 158, 160, 162 may include sidewalls S1, S2 and the base surfaces B₁₅₂, B₁₅₄, B₁₅₆ of the recesses 152, 154, 156, respectively. The voids 158, 160, 162 may each have a depth D₁₅₈, D₁₆₀, D₁₆₂ extending between the respective uppermost limits U₁₅₈, U₁₆₀, U₁₆₂ to the respective base surfaces B₁₅₂, B₁₅₄, B₁₅₆. For example, the depth D₁₅₈ of the void 158 may be the deepest compared to the voids 160, 162, while the depth D₁₆₀ of the void 160 may be the shallowest in comparison to the voids 158, 162. Meanwhile, the depth D₁₆₂ of the void 162 may fall between the depths D₁₅₈, D₁₆₀ of the voids 158, 160. In another example, the base surface B₁₅₂ of the void 158 may be at a level below the base surfaces B₁₅₄, B₁₅₆ of the voids 160, 162, the base surface B₁₅₄ of the void 160 may be at a level above the base surfaces B₁₅₂, B₁₅₆ of the voids 158, 162, and the base surface B₁₅₆ of the void 162 may be a level between the base surfaces B₁₅₂, B₁₅₄ of the voids 158, 160.

The voids 158, 160, 162 may not expose any conductive components, i.e., the metal wires 126 and the via structures 128 of the interconnect layers 110, 112. The voids 158, 160, 162 may be filled with air and may be referred to as an air gap. The voids 158, 160, 162 may contain a gas at or near atmospheric pressure, or at sub-atmospheric pressure, for example, a partial vacuum. The elemental composition of the gas in the voids 158, 160, 162 can include different gases and should not be construed as having any particular elemental composition, for example, any number and type of gases may be present in the voids. In an embodiment of the disclosure, each void 158, 160, 162 may each have a maximum width W₁₅₈, W₁₆₀, W₁₆₂ in an upper portion thereof at a level substantially coplanar with an upper surface of the uppermost metal layer, such as the second metal layer 122 of the second interconnect layer 112. The maximum widths W₁₅₈, W₁₆₀, W₁₆₂ may be the same as the maximum widths W₁₅₂, W₁₅₄, W₁₅₆ of the recesses 152, 154, 156 (FIG. 4) formed downwardly from the metal layer 122.

The dielectric layer 164 may be formed by a non-conformal deposition technique, such as a CVD process. The dielectric layer 164 may include a dielectric material that is capable of sealing the recesses 152, 154, 156 and also serving as an ILD layer for the next interconnect layer, such as a third interconnect layer 164. In an embodiment of the disclosure, the dielectric layer 164 may include the same dielectric material as the ILD 130, an interface between the dielectric layer 164 and the ILD 130 of the second interconnect layer 112 is diagrammatically shown by a dashed line for purposes of illustration. Processing of the semiconductor device 100 may continue with the formation of one or more interconnect structures over the second interconnect layer 112.

As presented in the above disclosure, semiconductor devices including voids having different depths and methods of forming the same are disclosed. The voids are formed in the BEOL region of the semiconductor device and can provide intra-metal layer and inter-metal layer electrical isolation through a single patterning process of the semiconductor device 100. The voids may be concurrently formed in one or more interconnect layers of the semiconductor device using grayscale lithography and etching processes and sealed with a dielectric material using a non-conformal deposition process. The voids may be contiguous through the one or more interconnect layers, i.e., there is no break in the voids, and the voids may extend laterally from sidewalls to sidewalls uninterrupted. The voids may extend through any number of interconnect layers, and the voids may have upper portions at a same level and lower portions extending to different depths within one or more interconnect layers. The deepest void may be preferably being vertically aligned to an active component in a FEOL region of the semiconductor device so as to improve the electrical performance thereof.

The terms “top”, “bottom”, “over”, “under”, and the like in the description and the claims, if any, are used for descriptive purposes and not necessarily for describing permanent relative positions. It is to be understood that the terms so used are interchangeable under appropriate circumstances such that the embodiments of the devices described herein are, for example, capable of operation in other orientations than those illustrated or otherwise described herein.

Additionally, the formation of a first feature over or on a second feature in the description that follows may include embodiments in which the first and second features are formed in direct contact and may also include embodiments in which additional features may be formed by interposing the first and second features, such that the first and second features may not be in direct contact.

Similarly, if a method is described herein as involving a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of features is not necessarily limited to those features but may include other features not expressly listed or inherent to such process, method, article, or device. Occurrences of the phrase “in an embodiment” herein do not necessarily all refer to the same embodiment.

In addition, unless otherwise indicated, all numbers expressing quantities, ratios, and numerical properties of materials, reaction conditions, and so forth used in the specification and claims are to be understood as being modified in all instances by the term “about”.

Furthermore, approximating language, as used herein throughout the specification and claims, may be applied to modify any quantitative representation that could permissibly vary without resulting in a change in the basic function to which it is related. Accordingly, a value modified by a term or terms, such as “approximately”, “about,” or “substantially” is not limited to the precise value specified. In some instances, the approximating language may correspond to the precision of an instrument for measuring the value. In other instances, the approximating language may correspond to within normal tolerances of the semiconductor industry. For example, “substantially coplanar” means substantially in a same plane within normal tolerances of the semiconductor industry, and “substantially perpendicular” means at an angle of 90 degrees plus or minus a normal tolerance of the semiconductor industry.

While several exemplary embodiments have been presented in the above-detailed description of the device, it should be appreciated that a number of variations exist. It should further be appreciated that the embodiments are only examples, and are not intended to limit the scope, applicability, dimensions, or configuration of the device in any way. Rather, the above-detailed description will provide those skilled in the art with a convenient road map for implementing an exemplary embodiment of the device, it is understood that various changes may be made in the function and arrangement of features and methods of fabrication described in an exemplary embodiment without departing from the scope of this disclosure as set forth in the appended claims.

What is claimed is:

1. A semiconductor device, comprising:
a device layer including an active component;
a first metal layer over the device layer;
a second metal layer over the first metal layer;
a first void vertically over the active component, the first void is through the first metal layer and the second metal layer; and
a second void adjacent to the first void, wherein an upper portion of the second void is at a same level as an upper portion of the first void.

2. The semiconductor device of claim 1, wherein each of the first void and the second void comprises a first sidewall and a second sidewall opposite the first sidewall, and the first sidewall and the second sidewall taper downwardly and inwardly from the second metal layer.

3. The semiconductor device of claim 2, wherein the first sidewalls and the second sidewalls of the first void and the second void have a substantially uniform gradient of an absolute value.

4. The semiconductor device of claim 3, wherein each of the first void and the second void comprises a base surface, and the base surface of the first void is at a level below the base surface of the second void.

5. The semiconductor device of claim 4, wherein the base surface of the first void is at a level below the first metal layer and the base surface of the second void is at a level above the first metal layer.

6. The semiconductor device of claim 3, wherein the first void has a first width between the corresponding first sidewall and the second sidewall, and the second void has a second width between the corresponding first sidewall and the second sidewall, wherein the first width and the second width vary based on the same linear function.

7. The semiconductor device of claim 6, wherein each of the first void and the second void has a maximum width, and the maximum widths of the first void and the second void are at the same level as an upper plane of the second metal layer.

8. The semiconductor device of claim 3, wherein the first metal layer is part of a first interconnect layer and the second metal layer is part of a second interconnect layer, wherein each of the first interconnect layer and the second interconnect layer comprises a corresponding interlayer dielectric therein, and the first void is laterally surrounded by the interlayer dielectrics of the first interconnect layer and the second interconnect layer.

9. The semiconductor device of claim 8, wherein the second interconnect layer further comprises a dielectric layer having a different dielectric material from the corresponding interlayer dielectric, and an edge of the dielectric layer is exposed in the first void and the second void.

10. The semiconductor device of claim 9, further comprising a third void having a third sidewall and a fourth sidewall taper downwardly and inwardly from the second metal layer, the third sidewall and the fourth sidewall have a same uniform gradient of an absolute value as the first sidewall and the second sidewall, and the dielectric layer of the second interconnect layer is exposed at a base surface of the third void.

11. The semiconductor device of claim 10, further comprising a third interconnect layer over the second interconnect layer, wherein an upper portion of the third void is in the third interconnect layer at the same level as the upper portions of the first void and the second void.

12. The semiconductor device of claim 3, wherein the first void and the second void are contiguous.

13. A method of forming a plurality of voids in a semiconductor device, comprising:
forming a device layer including an active component;
forming a first metal layer over the device layer;
forming a second metal layer over the first metal layer; and
forming a first void vertically over the active component and a second void adjacent to the first void, wherein the first void is through the first metal layer and the second metal layer, and an upper portion of the second void is at a same level as an upper portion of the first void.

14. The method of claim 13, wherein forming the first void and the second void comprises patterning the semiconductor device in a single patterning process to form a first recess and a second recess extending downwardly to different depths in the semiconductor device.

15. The method of claim 14, wherein each of the first recess and the second recess are formed with a first sidewall and a second sidewall opposite the first sidewall, and the first sidewalls and the second sidewalls of the first recess and the second recess taper inwardly from the second metal layer.

16. The method of claim 15, wherein the first sidewalls and the second sidewalls of the first void and the second void taper with a substantially uniform gradient in absolute value.

17. The method of claim 14, wherein the second recess is formed through the second metal and is at a level above the first metal layer.

18. The method of claim 14, wherein forming the semiconductor device further comprising:
forming a first interconnect layer in which the first metal layer and a first interlayer dielectric are part of;
forming a second interconnect layer over the first interconnect layer in which the second metal layer and a second interlayer dielectric are part of; and
the first recess is formed through and laterally surrounded by the interlayer dielectrics of the first interconnect layer and the second interconnect layer.

19. The method of claim 18, wherein forming the second interconnect layer further comprises forming a dielectric layer having a different dielectric material from the interlayer dielectric, wherein an edge of the dielectric layer is exposed in the first void and the second void.

20. The method of claim 18, further comprising forming a third interconnect layer over the second interconnect layer to seal the first recess and the second recess, wherein each of the first void and the second void comprises an upper portion in the third interconnect layer.
